(19) United States
(12) Patent Application Publication
(10) Pub. No.: US 2026/0148923 A1
(43) Pub. Date: May 28, 2026

(54) MULTI-BEAM PARTICLE BEAM SYSTEM HAVING AN ELECTROSTATIC BOOSTER LENS, METHOD FOR OPERATING A MULTI-BEAM PARTICLE BEAM SYSTEM, AND ASSOCIATED COMPUTER PROGRAM PRODUCT

(71) Applicant: Carl Zeiss MultiSEM GmbH, Oberkochen (DE)

(72) Inventors: Hans FRITZ, Grabs (DE); Thomas DIETERLE, Murrhardt (DE)

(21) Appl. No.: 19/451,553

(22) Filed: Jan. 16, 2026

Related U.S. Application Data
(63) Continuation of application No. PCT/EP2024/025211, filed on Jul. 18, 2024.

(30) Foreign Application Priority Data
Jul. 24, 2023 (DE) 10 2023 119 451.8

(51) Int. Cl. H01J 37/12; H01J 37/09; H01J 37/28

(52) U.S. Cl. CPC H01J 37/12; H01J 37/09; H01J 37/28; H01J 2237/1207

(57) ABSTRACT

A multi-beam particle beam system has a better resolution and a faster recording speed. An electrostatic booster lens is arranged in an upper focal plane of the objective lens level with the crossover region of the primary particle beams. The electrostatic booster lens is used to significantly increase the kinetic energy of the primary beams in the crossover region in a targeted manner, reducing the Coulomb interaction between the charged particles.

### CROSS-REFERENCE TO RELATED APPLICATIONS

The present application is a continuation of, and claims benefit under 35 USC 120 to, international application No. PCT/EP 2024/025211, filed Jul. 18, 2024, which claims benefit under 35 USC 119 of German Application No. 10 2023 119 451.8, filed Jul. 24, 2023. The entire disclosure of each of these applications is incorporated by reference herein.

### FIELD

The disclosure relates to multi-beam particle beam systems which operate with a plurality of individual charged particle beams. For example, the disclosure relates to a multi-beam particle beam system having an electrostatic booster lens, to a method for operating a multi-beam particle beam system, and to an associated computer program product.

### BACKGROUND

With the ongoing development of ever smaller and ever more complex microstructures such as semiconductor components, there is a general desire to further develop and optimize planar production techniques and inspection systems for producing and inspecting small dimensions of the microstructures. For instance, the development and production of the semiconductor components involve monitoring of the design of test wafers, and the planar production techniques involve process optimization for reliable production with high throughput. Moreover, there have been recent demands for an analysis of semiconductor wafers for reverse engineering and for a customized, individual configuration of semiconductor components. Therefore, there is a general desire for inspection mechanism which can be used with high throughput to examine the microstructures on wafers with high accuracy.

Typical silicon wafers used in the production of semiconductor components have diameters of up to 300 mm. Each wafer is typically subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure dimension of the integrated semiconductor structures in this case extends from a few μm to the critical dimensions (CD) of a few nanometers, with the structure dimensions becoming even smaller in the near future. The expectation is that in future the structure dimensions or critical dimensions (CD) will correspond to the 3 nm, 2 nm or even smaller process nodes of the International Technology Roadmap for Semiconductors (ITRS). In the case of the aforementioned small structure dimensions, it is desirable to relatively quickly identify defects of the order of the critical dimensions over a relative large area. For several applications, the desired accuracy of a measurement provided by inspection equipment is even higher, for example by a factor of two or one order of magnitude. For instance, it is desirable to be able to measure a width of a semiconductor feature with an accuracy of better than 1 nm, for example 0.3 nm or even less, and it is desirable to be able to determine a relative position of semiconductor structures with an overlay accuracy of better than 1 nm, for example 0.3 nm or even less.

The MSEM, a multi-beam scanning electron microscope, is a relatively recent development in the field of charged particle inspection systems or particle microscopes. For instance, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. For instance, 4 to 10,000 individual electron beams can be provided as primary radiation, with each individual electron beam being separated from an adjacent individual electron beam by a pitch of 1 to 200 micrometers. For example, an MSEM has approximately 100 separate individual electron beams (“beamlets”), which for instance are arranged in a hexagonal raster, with the individual electron beams being separated by a pitch of approximately 10 μm.

The bundle of electron beams or, more generally, individual charged particle beams is created by virtue of a primary charged particle beam being directed at a multi-aperture arrangement comprising at least one multi-aperture plate with a plurality of openings. Some of the charged particles of the primary charged particle beam impinge on the multi-aperture plate and are absorbed there, and another portion of the primary charged particle beam passes through the openings in the multi-aperture plate, whereby a first individual charged particle beam is formed in the beam path downstream of each opening, the cross section of the first individual charged particle beam being defined by the cross section of the opening.

The plurality of individual charged particle beams (primary beams) are focused on a surface of a sample to be examined by way of a common objective lens. For example, the sample can be a semiconductor wafer which is secured to a wafer holder mounted on a movable sample stage. When the wafer surface is illuminated by the first individual charged particle beams, interaction products, e.g. secondary electrons or backscattered electrons, emanate from the surface of the object. Their start points correspond to those locations on the sample/object on which the plurality of individual primary particle beams are focused in each case. The amount and the energy of the interaction products depend on the material composition and the topography of the wafer surface. The interaction products form several secondary individual particle beams (secondary beams), which are collected by the common objective lens and, after passing through a projection imaging system of the multi-beam inspection system, are incident on a detector arranged in a detection plane. The detector comprises several detection regions, each of which may comprise several detection pixels, and the detector acquires an intensity distribution for each of the secondary individual particle beams. An image field of 100μm ×100μm, for example, is obtained in the process.

A known multi-beam electron microscope comprises a sequence of electrostatic and magnetic elements. At least some of the electrostatic and magnetic elements are adjustable in order to adapt the focus position and the stigmation of the plurality of individual charged particle beams. Such a multi-beam system with charged particles moreover can comprise at least one crossover plane of the primary or the secondary individual charged particle beams. Moreover, such a system can comprise detection systems in order to facilitate the adjustment. Such a multi-beam particle microscope can comprise at least one collective deflection scanner for collective scanning of a region of the sample surface via the plurality of individual primary particle beams in order to obtain an image field of the sample surface. In this case, the bundle of primary individual particle beams can be systematically scanned over the surface of the sample, and an electron-microscopic image of the sample can be created in the manner conventional for scanning electron microscopes.

What is known as a beam splitter (or alternatively beam separator or beam divider) can be used to separate the particle-optical beam path of the primary beams from the particle-optical beam path of the secondary beams. In this case, separation is implemented via special arrangements of magnetic fields and/or electrostatic fields, for example via a Wien filter.

Usually, resolution and scanning speed are two relevant characteristics of a particle microscope or, more generally, of a multi-beam particle beam system. This applies especially to a use of a particle microscope in the semiconductor industry. The scanning speed is generally a function of the beam current. Use of a high beam current also can allow a high scanning speed, enabling a faster image creation.

Higher beam currents usually create more Coulomb interactions between the charged particles or particle beams. These Coulomb interactions can be a source or cause of aberrations. Higher beam currents therefore can reduce the resolution of a particle microscope.

The characteristics of resolution on the one hand and scanning speed on the other hand are at least partially decoupled from one another in a multi-beam particle beam system, to be precise due to the division of the overall beam current into a plurality of spatially separated individual charged particle beams. In comparison with a single beam particle beam system, the dependence of the resolution on the overall beam current can thus be weaker in a multi-beam particle beam system for systemic reasons.

Bringing about a spatial separation of the individual particle beams along the entire illumination path is also not generally possible in the case of a multi-beam particle beam system operating with a single column. Instead, the laws of optics can postulate that the primary path contains at least one crossover plane or crossover region where the individual charged particle beams cross over or penetrate through one another. Thus, more Coulomb interactions tend to occur in this crossover region—also referred to as pupil plane—which can promote the creation of aberrations, and this in turn can have an adverse effect on the resolution of the multi-beam particle beam system. Even in multi-beam particle beam systems, the overall beam current therefore cannot in general simply be increased further as desired, to be precise either by an increase in the individual beam currents or by an increase in the number of individual particle beams.

The strength of the Coulomb interaction is also known to depend on the electric potential or kinetic energy of the charged particles. A high kinetic energy tends to reduce the arising Coulomb interaction. A known multi-beam particle beam system therefore already can operate at high electric potentials and with high kinetic energies of the particles within the column. To this end, a high voltage can be applied to the particle source or a high-voltage potential is provided for the particle source; substantially, the same applies for the sample stage or at the sample. For example, work can be conducted there in each case at a high voltage of in each case approximately (+/−)25 kV, (+/−)28 kV or (+/−)30 kV. The charged particles or particle beams are accelerated very strongly in the region of the particle source, then move at a very high speed through substantially the entire column, and only are decelerated again just prior to arrival at the sample. In theory, one option therefore can be to increase (in terms of absolute value) the high voltage applied to the particle source and to the sample even further. However, in practice this can lead to difficulties, especially in the region of the sample or sample stage. Increasing the high voltage applied to the sample stage (or simply stage) and hence to the sample generally is only implementable, if at all, with difficulties.

DE 10 2021 105 201 A1 discloses a multiple particle beam microscope having a fast autofocus correction lens system with either a two-part autofocus correction lens or else a system of at least two fast autofocus correction lenses.

S. Beck et al., “Low voltage probe forming columns for electrons”, Nuclear Instruments and Methods in Physics Research Section A 363(1995 ), pp. 31-42, discloses a known relationship between the provision of a high beam energy and a reduced interaction between the electrons in an individual beam. An examined sample is not at high voltage potential.

### SUMMARY

The present disclosure seeks to provide a multi-beam particle beam system with an improved resolution which, however, does not involve a reduction in the scanning speed. For example, the disclosure seeks to reduce the aberrations caused by Coulomb interaction in the primary path of a multi-beam particle beam system operating with a single column. Moreover, it is desirable for this reduction to be easy to implement from a technological point of view.

The disclosure seeks to vary the numerical aperture in the object plane during the operation of the multi-beam particle beam system. The numerical aperture generally depends on the overall beam current and on the landing energy. The modification of one of these quantities can lead to a modification in the optimal numerical aperture for which the resolution is optimal. It is desirable to be able to adapt or adjust the numerical aperture.

The disclosure seeks to modify a working distance or the position of the object plane in relation to the objective lens, for example without this modifying the magnification or the telecentricity of the first individual particle beams upon incidence on the object plane.

The disclosure involves the concept that the kinetic energy of the first individual charged particle beams is not to be increased along the entire illumination column. Instead, the kinetic energy of the first individual charged particle beams is to be increased only in sections, for example purposefully only at the location with the most relevant Coulomb interactions, i.e. in the crossover region. This approach can significantly reduce Coulomb interaction-induced aberrations and simultaneously can avoid issues that could occur in the case of the application of an even greater high voltage (in terms of absolute value) to the sample stage/to the sample, which can be of any type. An electrostatic booster lens can be implemented for the purpose of increasing the kinetic energy in sections. For example, the implementation is in a manner which does not entail relatively highly complex modifications of particle-optical imaging parameters but, by contrast, provides one or more additional degrees of freedom for setting the multi-beam particle beam system.

According to a first aspect, the disclosure relates to a multi-beam particle beam system comprising the following features: a particle source for emitting a charged particle beam; a multi-aperture arrangement comprising at least one multi-aperture plate having a multiplicity of passage openings, the multi-aperture arrangement being configured to create a first field of a plurality of first individual charged particle beams from the charged particle beam; a first particle-optical unit with a first particle-optical beam path, configured to image the created first individual particle beams on a sample surface in the object plane such that the first individual particle beams are incident on the sample surface at incidence locations which form a second field; a magnetic and/or electrostatic objective lens, through which the first individual particle beams pass; a sample stage for arranging a sample with a sample surface in the object plane; an electrostatic booster lens, with the first particle-optical beam path comprising a crossover region of the first individual charged particle beams, which is arranged in the region of an upper focal plane of the objective lens, and with the electrostatic booster lens being arranged in the region of this crossover region; a voltage provision unit; and a controller for controlling the multi-beam particle beam system, wherein the controller is configured to provide a booster high voltage VB at the electrostatic booster lens via the voltage provision unit, in such a way that the first individual charged particle beams pass through sections of the crossover region with a substantially increased kinetic energy so that aberrations on account of Coulomb interaction between the individual particle beams are reduced within the crossover region.

The first individual charged particle beams can be, for example, electrons, positrons, muons or ions or other charged particles. It is desirable for the number of first individual particle beams to be 3n(n−1)+1, where n is any natural number. The first individual particle beams can then be arranged in a hexagonal field. However, other arrangements of the first individual particle beams are also possible. The second individual particle beams can be backscattered electrons or else secondary electrons. In this case, for analysis purposes it is desirable for the low-energy secondary electrons to be used to create the image. However, it is also possible for mirror ions/mirror electrons to be used as second individual particle beams, i.e. first individual particle beams undergoing reversal directly upstream of the object or at the object.

The sample can be of any type. Within the scope of this patent application, the term sample is used in general to denote a substrate to be examined or processed. Thus, the term sample is to be interpreted broadly. For example, examples of a sample can be wafers, lithography masks or mask blanks.

The voltage provision unit according to the disclosure can be embodied in one or more parts. For example, it might be of a modular design, for example with a module for providing a high voltage and a module for providing a low voltage. In this patent application, the expressions “high voltage” and “low voltage” are used in the sense conventional in electrical engineering: In DC voltage operation, a voltage V>1500 V is referred to as “high voltage”. A voltage V≤1500 V is referred to as “low voltage”. The low voltage provided at the multi-aperture arrangement according to an embodiment of the disclosure can be an extra-low voltage, with the following applying to an extra-low voltage within DC voltage operation: V≤120 V. It can also be ground potential.

According to the disclosure, the electrostatic booster lens can be arranged in the first particle-optical beam path in the region of the crossover region of the first individual charged particle beams. The crossover region would be a crossover plane in the ideal case; however, this is not the case in practice, and so reference is made to a crossover region instead. The electrostatic booster lens can be arranged in the region of this crossover region. It can act on the charged first individual particle beams in the region of the crossover region. The manner of this effect can be comparatively abrupt, and this is suggested by the term “booster”. It is possible to use the electrostatic booster lens to bring about a relatively significant increase in the kinetic energy of the first individual particle beams over a comparatively very short section of the first particle-optical beam path, with the result that the first individual particle beams pass through the crossover region with a significantly increased kinetic energy. The consequence can be a significant reduction of aberrations on account of a Coulomb interaction of the first individual particle beams within the crossover region. Moreover, it is possible for the increased kinetic energy is only present in sections, i.e. the electrostatic booster lens does not increase the kinetic energy of the individual charged particle beams for substantially the remaining section of the particle-optical beam path to the objective lens or to the sample; instead, the significantly increased kinetic energy can be at least substantially reduced again straight after the passage through the crossover region. The electrostatic booster lens can bring about a significant increase in the kinetic energy of the first individual charged particle beams only in a section.

In the particle-optical beam path between the particle source and the sample, the first individual particle beams can have their maximum kinetic energy in the region of the booster lens, and hence in the crossover region, according to an embodiment of the disclosure, wherein, in terms of absolute value, the following relation can apply to the maximum electric potential growth ΔVB brought about by the booster lens: ΔVB≥10 kV, for example ΔVB≥15 kV. This maximum electric potential growth ΔVB can be very high in comparison with typical overall potential changes in the particle-optical beam path. For example, the electric potential growth ΔVB brought about via the electrostatic booster lens might be ≥30%, ≥40% or ≥50% of the potential difference which the charged particles, such as electrons, have already passed through along their path from the particle source to the entrance into the booster lens. For example, it is possible that a negative potential or negative high voltage of −30 kV is applied to the particle source. For example, the electrons prior to entrance into the booster lens are approximately at ground potential and have a kinetic energy of 30 kV. Then, their kinetic energy can be increased by a further ≥10 kV or ≥15 kV via the booster lens, corresponding to an increase of ≥⅓ or ≥50% of their kinetic energy.

According to an embodiment of the disclosure, the controller can be configured to provide a first high voltage V1 at the particle source via the voltage provision unit. Moreover, the controller can be configured to provide at most a low voltage Vm at the multi-aperture arrangement via the voltage provision unit, and the controller can be configured to provide a second high voltage V2 at the sample stage, and hence at the sample, via the voltage provision unit.

According to an embodiment of the disclosure, the first high voltage V1 and the second high voltage V2 have the same sign. What moreover applies in this embodiment variant is that, in terms of absolute value, the following relation can apply to the first high voltage V1 at the particle source: 20 kV≤V1≤40 kV, for example 25 kV≤V1≤35 kV. Moreover, in terms of absolute value, the following relation can apply to the second high voltage V2 at the sample stage: 20 kV≤V2≤40 kV, such as 25 kV≤V2≤35 kV. Moreover, in terms of absolute value, the following relation can apply to the low voltage Vm at the multi-aperture arrangement: 0 V≤Vm≤100 V, such as Vm=0 V or ground potential. The first high voltage V1 and the second high voltage V2 having the same sign can be explained by fact that the first individual charged particle beams are initially accelerated but then also decelerated significantly again before the sample is reached. Typical landing energies upon incidence on the sample are a few hundred eV, for example 900 eV, such as 1.2 keV or 1.5 keV. The high voltages V1 and V2 specified above and also the low voltage Vm or ground potential at the multi-aperture arrangement are voltages that may have already been applied in this manner to the multi-beam particle beam system in the case of multi-beam particle systems. Within the scope of the present disclosure, it is possible that these values are not changed. This can help prevent issue that might arise when an even greater high voltage is applied to the sample stage, for example. It is also desirable to keep the multi-aperture arrangement or the so-called micro-optical unit at ground potential. This can help avoid issues, for example in the electronics and the control thereof. The electrostatic booster lens can be used to make the first individual charged particle beams harder in the crossover region, in order to reduce

the Coulomb interactions. The use of a booster lens can be a relatively elegant solution in comparison with a solution that would provide ever higher high voltages both at the particle source and at the sample stage.

According to an embodiment of the disclosure, the booster high voltage VB has a different sign to the first and the second high voltage. In terms of absolute value, the following relation can apply to the booster high voltage VB at the electrostatic booster lens: VB≥10 kV, for example VB≥15 kV. If particle source and sample stage are at a negative high voltage potential, then a positive high voltage potential can be applied to the electrostatic booster lens according to this embodiment of the disclosure. This embodiment variant concretizes above-described desirable features of the arrangement of the electrostatic booster lens.

According to an embodiment of the disclosure, the following relation applies to a length LB of the electrostatic booster lens along the particle-optical axis Z: 2 mm≤LB≤10 mm. The electrostatic booster lens or its lens field has a relatively small extent along the particle-optical axis Z, meaning that the sectional increase of the kinetic energy of the first individual charged particle beams and also the deceleration thereof again can occur over a very short distance. The length LB of the electrostatic booster lens is measured along the extent of the effectiveness of the electrostatic booster lens, which substantially corresponds to the path between the electrodes or counter electrodes of the electrostatic booster lens. According to an embodiment of the disclosure, the following relation applies to a length LBm of a central electrode of the electrostatic booster lens: 1.5 mm≤LBm≤4.5 mm.

The electrostatic booster lens can be substantially embodied as an Einzel lens according to an embodiment variant of the disclosure. A characteristic of an Einzel lens is that the charged particles have the same kinetic energy upon entrance into and exit from the Einzel lens. They are only accelerated in the interior of the Einzel lens. It is possible for this to apply to the electrostatic booster lens at least in principle, and so the relatively

significant increase in the kinetic energy and also its fall back down can be achieved section-wise in the crossover region. This can help ensure the booster function. The counter electrodes of the Einzel lens might not be at exactly the same potential. This is desirable in terms of correcting particle-optical imaging parameters. Details in this respect will be discussed hereinbelow.

According to an embodiment of the disclosure, the lens effect of the electrostatic booster lens is realized at least in part via an offset voltage at a multi-pole electrode. This offset voltage at a multi-pole electrode, for instance a quadrupole, octupole or twelve-pole electrode, likewise can allow setting of a lens effect of the multi-pole electrode. An offset voltage can be applied in this case for the purpose of realizing a counter electrode/the counter electrodes in a multi-pole electrode/the multi-pole electrodes. However, it is also possible that an offset voltage is applied to a multi-pole electrode for the purpose of realizing the central electrode of an Einzel lens. These embodiment variants can allow multi-pole electrodes already arranged in the region of the crossover region in any case to be used for the design of the electrostatic booster lens. For example, a collective scan deflector is provided in the region of the beam crossover or in the region of the crossover region, and it may comprise corresponding multi-pole electrodes for the collective deflection of the first individual particle beams.

According to an embodiment of the disclosure, the multi-beam particle beam system comprises a beam tube arrangement, within which at least the first individual particle beams are guided at least in sections, and wherein the beam tube arrangement comprises a beam tube extension which projects into the objective lens. In this case, the electrostatic booster lens can be arranged within this beam tube extension. In this embodiment variant of the disclosure, the electrostatic booster lens can be embodied for example as an Einzel lens with a first electrode, a second (central) electrode and a third electrode. In this context, the beam tube extension can be substantially at ground potential.

According to an alternative embodiment of the disclosure, the multi-beam particle beam system comprises a beam tube arrangement, within which at least the first individual particle beams are guided at least in sections. In this context the beam tube arrangement can comprise a beam tube interruption in the region of the crossover region, and the beam tube arrangement is subdivided into a first beam tube section and a second beam tube section via the beam tube interruption. According to this embodiment, a first upper electrode of the electrostatic booster lens can then be formed via the first beam tube section, to which no more than a low voltage VT1 has been applied. Moreover, a second central electrode of the electrostatic booster lens can be arranged within the beam tube interruption, at which the booster high voltage VB is provided. Moreover, a third lower electrode of the electric booster lens can be formed via the second beam tube section, to which no more than a low voltage VT2 has been applied. The low voltages VT1 and VT2 might be identical in this case, but they might also deviate from one another. The electrostatic booster lens can once again very easily be substantially embodied as an Einzel lens according to this embodiment of the disclosure. This electrostatic booster lens can likewise be produced very easily from a constructional point of view.

According to an embodiment of the disclosure, the multi-beam particle beam system comprises a collective scan deflector having an upper deflection unit in the upper crossover region and having a lower deflection unit in the lower crossover region. The crossover plane, i.e. the idealized plane of beam crossover, can be situated between the upper and lower crossover region. According to this embodiment variant of the disclosure, the central electrode of the electrostatic booster lens can be arranged between the upper deflection unit and the lower deflection unit. With its central electrode, the electrostatic booster lens therefore can be situated very centrally in the region of the crossover region or level with the theoretical crossover plane. As a result, the electrostatic booster lens can have a relatively targeted effect in the crossover region of the individual particle beams. A respective counter potential to the central electrode in the form of an offset voltage can be applied to the upper deflection unit and to the lower deflection unit.

The provision of an electrostatic booster lens in the crossover region or as exactly level with the crossover as possible has a further desirable feature or a further consequence: a basic principle of multi-beam particle beam systems is that particle-optical imaging parameters cannot be set independently of one another. A modification of one parameter usually entails the need to adapt another imaging parameter. However, particle-optical imaging parameters are at least largely decoupled from one another in the crossover region of the first individual particle beams. The electrostatic booster lens substantially only influences the α beam or axial beam and hence the focusing of the first individual particle beams, while the γ beam or field beam runs through the axis of symmetry of the system and thus remains substantially uninfluenced by the electrostatic booster lens. The provision of an electrostatic booster lens in the crossover region thus has relatively minor consequences in relation to the imaging properties of the multi-beam particle beam system and does not lead to a complete maladjustment of the overall system. Instead, the electrostatic booster lens substantially causes slightly changed focusing of the first individual particle beams upon departure from the electrostatic booster lens. This modified focal position can be corrected or set comparatively easily.

According to the disclosure, it might be the case that the multi-beam particle beam system is not only to be designed once for a specific booster high voltage or booster voltage VB; instead, it is even possible for this booster voltage to be varied and used for the purpose of setting a modified numerical aperture NA of the first individual particle beams upon incidence on the object plane.

According to an embodiment of the disclosure, the multi-beam particle beam system moreover comprises a first setting mechanism, wherein the controller is configured to control the first setting mechanism such that the booster high voltage VB applied to the electrostatic booster lens is modified. As a result, in turn, a working distance WD of the first individual particle beams and/or a numerical aperture NA of the first individual particle beams upon incidence on the object plane can be modified.

According to an embodiment of the disclosure, the multi-beam particle beam system moreover comprises a second setting mechanism that differs from the first setting mechanism, and the controller is configured to control the second setting mechanism such that the modified working distance WD of the first individual particle beams is corrected and/or such that the modified numerical aperture NA of the first individual particle beams upon incidence on the object plane is corrected. The second setting mechanism can allow particle-optical properties, which would otherwise change on account of the modified setting of the electrostatic booster lens, to be kept constant. Naturally, such a correction may be superfluous, however, if the modified setting of the electrostatic booster lens is used deliberately for the purpose of modifying the particle-optical parameters. The electrostatic booster lens can represent an additional degree of freedom for the adjustability of particle-optical imaging parameters. For example, it can be used to purposefully set the numerical aperture NA and thus optimize the resolution. Details regarding degrees of freedom and the use thereof when setting particle-optical imaging parameters and the numerical aperture for example are found e.g. in the international patent application WO 2021/018332 A1, the disclosure of which is fully incorporated by reference in the present patent application.

The second setting mechanism, which differs from the first setting mechanism, can be designed in different ways. It can be embodied in one part or multiple parts. It is possible to provide separate second setting mechanism for the multi-beam particle beam system; however, it is also possible to use or appropriately control particle-optical elements of the multi-beam particle beam system, which are already present in any case, as second setting mechanism.

According to an embodiment of the disclosure, the second setting mechanism is configured to bring about a modified excitation of the objective lens and/or of a field lens. If the first particle-optical beam path is considered from an intermediate image plane to the object plane, then the latter substantially can correspond to a 4f system. For example, two focal lengths f1 may be given here via a field lens, and two further focal lengths f2 may be given via the objective lens of the multi-beam particle beam system. The electrostatic booster lens can be situated in the region of the crossover region and hence is substantially level with what is known as the pupil plane. The imaging properties of the so-called 4f system can be retained provided a focal length of the objective lens and a focal length of the field lens are modified at the same time. It is possible for the overall system to remain telecentric in that case; the imaging scale changes only insubstantially and its change can be tolerated. Moreover, the pupil plane can remain substantially stationary and the position of the electrostatic booster lens remains within the crossover region. For example, the objective lens and the field lens can be magnetic lenses, the change in excitation of which can be obtained in each case by a modification of the associated lens current.

It is possible that a change in the refractive power of the objective lens can also be achieved by measures other than changing the excitation of the objective lens. It is possible that elements that modify the speed of the charged particles in the first individual particle beams within the magnetic field of the objective lens can serve for this measure, whereby the objective lens refractive power can be varied in turn.

According to an embodiment of the disclosure, the second setting mechanism is configured to bring about a modified control of the collective scan deflector. A slightly modified offset potential can be applied to the upper and/or lower deflectors of the collective scan deflector; this causes a corresponding lens effect and a change in speed in

the case of modified offset potentials, which in turn modifies the refractive power of the objective lens for these individual particle beams. In this case, the offset voltage differs from a voltage applied to a/the beam tube.

According to an embodiment of the disclosure, the second setting mechanism is configured to apply a modified voltage VT2 to the second beam tube section. This can result in a modified lens effect and a modified speed in the interior of the magnetic field of the objective lens.

According to an embodiment of the disclosure, the second setting mechanism comprises an electrostatic correction element arranged in a/the magnetic field of the objective lens. For example, this may be an autofocus correction lens and/or a multi-pole corrector.

According to a further embodiment of the disclosure, the second setting mechanism can be configured not to modify the focal length of the objective lens but only to adapt the focal length of a field lens. In relation to the aforementioned 4f system, this can modify the originally telecentric system to become a non-telecentric system. Accordingly, it can be a setting option or correction option to adapt the input telecentricity of the individual particle beams upon entrance into the 4f system.

According to an embodiment of the disclosure, the multi-beam particle beam system moreover comprises an intermediate image plane and a telecentricity correction mechanism, such as an additional field lens, in the first particle-optical beam path, with the telecentricity correction mechanism being arranged between the multi-beam generator and the intermediate image plane. In this case, the controller is configured to control the telecentricity correction mechanism, such as the additional field lens, such that an input telecentricity of the first individual particle beams can be varied in the intermediate image plane.

An extraction field between the objective lens and the sample can remain unmodified in both cases (modifying both the objective lens focal length and the field lens focal length, or no modification of the objective lens focal length and only modifying the field lens focal length).

According to an embodiment of the disclosure, the multi-beam particle beam system is configured for a telecentric incidence of the first individual particle beams on the object plane. This is desirable especially for semiconductor samples with HV structures; however, it may also be desirable for other samples.

According to an embodiment of the disclosure, the multi-beam particle beam system moreover comprises the following: a detection system with a plurality of detection regions which form a third field; a second particle-optical unit with a second particle-optical beam path, configured to image second individual particle beams, which emanate from the incidence locations in the second field, on the third field of the detection regions of the detection system; a beam splitter arranged in the first particle-optical beam path between the multi-aperture arrangement and the objective lens and arranged in the second particle-optical beam path between the objective lens and the detection system, wherein the second individual particle beams also pass through the objective lens.

According to an embodiment of the disclosure, the multi-beam particle beam system is an inspection system, such as a multi-beam particle microscope. According to an alternative embodiment of the disclosure, the multi-beam particle beam system is a lithography system. For example, lithography systems can be used to produce lithography masks or wafers by direct writing lithography. However, the multi-beam particle beam system according to the disclosure may also be of another type.

The above-described embodiments of the disclosure in accordance with the first aspect can be combined with one another in full or in part, provided that no technical contradictions arise as a result.

According to a second aspect, the disclosure relates to a method for operating a multi-beam particle beam system, for example a multi-beam particle beam system as described above in several embodiment variants. In this context, the method includes the following steps: (a) providing a multi-beam particle beam system with a crossover region of first individual charged particle beams in the illumination beam path in an upper focal plane of an objective lens; and (b) section-wise significantly increasing the kinetic energy of the first individual particle beams in the crossover region for the purpose of significantly reducing the Coulomb interaction between the first individual charged particle beams. For example, this can be carried out by the implementation of an electrostatic booster lens in the crossover region, as has already been described in several embodiment variants in the context of the first aspect of the disclosure.

According to an embodiment of the disclosure, the method moreover includes the following steps: (c) modifying the maximum kinetic energy of the first individual particle beams in the crossover region, whereby at least one imaging parameter of the multi-beam particle beam system is modified upon incidence of the first individual particle beams on an object plane; and (d) correcting the at least one modified imaging parameter. For example, this imaging parameter can be the modified working distance WD or the numerical aperture NA of the first individual particle beams upon incidence on the object plane. In addition to that or in the alternative, particle-optical parameters such as telecentricity or magnification can be set or adapted.

Otherwise, everything that has already been explained in the context of the first aspect of the disclosure also can apply in the context of the second aspect of the disclosure. For example, this also relates to definitions and certain embodiments.

According to a third aspect, the disclosure relates to a computer program product having a program code for performing the method as described above in the context of the second aspect of the disclosure. In this case, the program code can be written in any desired programming language. The program code can be embodied in one part or in multipartite fashion. For example, it is desirable to provide a separate program code relating to the control of the electrostatic booster lens. However, this need not be the case; the program code can also be structured differently.

### BRIEF DESCRIPTION OF THE DRAWINGS

The disclosure will be understood even better with reference to the accompanying figures. In the figures:

FIG. 1: schematically shows a multi-beam particle beam system using the example of a multi-beam particle microscope;

FIG. 2: schematically shows a detail of the illumination column of the multi-beam particle beam system of FIG. 1 together with a schematic representation of the kinetic energy of primary beams when traversing the illumination column;

FIG. 3: schematically shows an image sensor of the multi-beam particle beam system of FIG. 1;

FIG. 4: schematically shows an electrostatic booster lens and the control thereof, and also its influence on the kinetic energy of the charged particles traversing it;

FIG. 5: schematically shows an electrostatic booster lens and the control thereof, and also its influence on the kinetic energy of the charged particles traversing it;

FIG. 6: schematically shows an arrangement of an electrostatic booster lens in a multi-beam particle beam system;

FIG. 7: schematically shows an electrostatic booster lens and the control thereof, and also its influence on the kinetic energy of the charged particles traversing it, in the case of an arrangement of the booster lens in accordance with FIG. 6;

FIG. 8: schematically shows an arrangement of an electrostatic booster lens in a multi-beam particle beam system;

FIG. 9: schematically shows a 4f system with an electrostatic booster lens in a crossover region, and the influence of the electrostatic booster lens on the particle-optical beam path; and

FIG. 10: schematically shows a flowchart of a method according to the disclosure.

### DETAILED DESCRIPTION

To the extent that this is possible, components with a similar function and structure are denoted by similar or identical reference signs in the exemplary embodiments of the disclosure described below. In so doing, elements of an array, for example the plurality of first individual charged particle beams, might be denoted via one reference sign. Depending on context, the same reference sign might also denote an individual element of the array elements. Each first individual charged particle beam (3.1, 3.2, 3.3) is an individual particle beam or beamlet of the multiplicity of first individual charged particle beams (3).

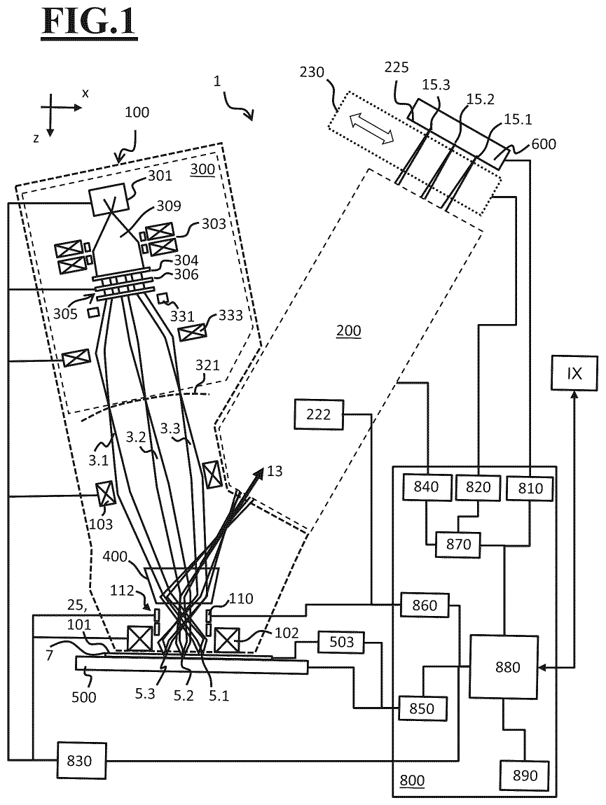

The schematic illustration in FIG. 1 shows fundamental features and functions of a multi-beam particle beam system 1. It is to be observed that symbols used within the figure have been selected on account of the respective functionality that they symbolize. The type of the shown system 1 is that of a multi-beam particle microscope 1. However, the disclosure is not restricted to multi-beam particle microscopes and the illustration in FIG. 1 serves only illustrative purposes. The multi-beam particle beam system 1 operates with a plurality of first individual charged particle beams 3 to create a corresponding plurality of incidence locations or beam spots 5 of the first individual particle beams on a surface 25 of an object 7, wherein the object 7 or the sample 7 might be for example a wafer or mask substrate which is arranged with its surface 25 in an object plane 101 of an objective lens 102. For reasons of simplicity, only three first individual charged particle beams 3.1 to 3.3 and correspondingly three incidence locations 5.1 to 5.3 of the first individual charged particle beams on the object plane 101 have been illustrated. The features and functions of the multi-beam particle beam system 1 can be implemented using electrons or else other charged particles such as for example ions and for example helium ions. Further details regarding the multi-beam particle beam system 1 are disclosed in the international patent application WO 2021/018332 A1, filed on Jun. 16, 2021. The disclosure of this patent application is fully incorporated by reference in the present patent application.

The multi-beam particle beam system 1 comprises an object illumination unit 100 and a detection unit 200, and also a beam splitter 400 for separating a secondary particle-optical beam path 13 from a first particle-optical beam path 11. The object illumination unit 100 comprises a beam creation apparatus 300 for creating a plurality of first individual charged particle beams 3 and is adapted to focus the plurality of first individual charged particle beams 3 in the object plane 101, in which the surface 25 of an object 7 or wafer 7 has been positioned via a sample stage 500.

The beam creation apparatus 300 creates a plurality of first individual charged particle beam spots in an intermediate image plane 321. The beam creation apparatus 300 comprises at least one source 301 of charged particles, for example electrons. The at least one particle source 301 emits a divergent charged particle beam which is collimated via at least one collimation lens 303 such that a collimated or parallel first charged particle beam 309 is formed. The collimation lens 303 normally comprises one or more electrostatic or magnetic lenses or a combination of electrostatic and magnetic lenses. The collimated primary charged particle beam 309 is incident on the multi-beam generator 305. A multi-beam generator 305 is described for example in US 2019/0259575 A1 and US 10 741 355 B1; both documents are fully incorporated by reference in the present patent application. The multi-beam generator 305 comprises a first multi-aperture plate or filter plate 304 which is illuminated by the then collimated first particle beam 309. The first multi-aperture plate or filter plate 304 comprises a plurality of apertures in a grid arrangement serving to create the plurality of first individual charged particle beams 3, with these first individual charged particle beams 3 being formed when charged particles in the first charged particle beam 309 pass through the corresponding openings. The multi-beam generator 305 moreover comprises at least one further multi-aperture plate 306 arranged downstream of the first multi-aperture plate or filter plate 304 in the direction of the particle-optical beam path. In this case, the direction of the particle-optical

beam path is specified by the movement direction of the charged particles in the particle beam 309. According to one example, a second multi-aperture plate 306 may comprise four or eight electrostatic elements for each of the plurality of openings, for example in order to individually deflect each of the first individual particle beams 3. Together with a second field lens 303, the plurality of first individual charged particle beams 3 are focused in the intermediate image plane 321 or in the direct vicinity thereof. The charged particle source 301 and each of the active multi-aperture plates 306 are controlled via the primary path controller module 830, which is a constituent part of the controller 800 of the multi-beam particle beam system 1.

The plurality of focal points of the first individual charged particle beams 3, which pass through the intermediate image plane 321, are imaged via a field lens group 103 and an objective lens 102 in the object plane 101, in which the surface 25 of the object 7 is positioned. An electrostatic deceleration field is created between the objective lens 102 and the object surface 25 by applying a voltage to the object 7 via a sample voltage supply 503. The electrostatic deceleration field created via the sample voltage supply 503 is used to set a landing energy EL of the first individual charged particle beams, for example primary electrons, for example to less than 1 keV, less than 800 eV, less than 500 eV, less than 300 eV or even lower.

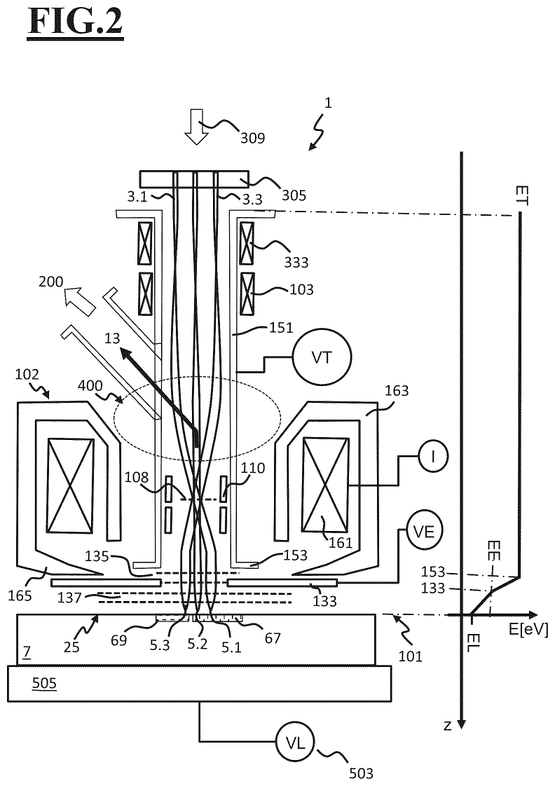

FIG. 2 schematically illustrates further details of the electrostatic deceleration field. A plurality of individual charged particle beams 3 are created from the collimated electron beam 309 via the multi-aperture arrangement 305 or via the multi-beam generator 305. Only three individual particle beams 3.1 to 3.3 have been depicted for reasons of simplicity; however, it is naturally possible to create more first individual charged particle beams 3, for example more than 60, more than 90 or even more than 300 individual particle beams. A beam tube 151 in which the plurality of individual particle beams 3 are guided is arranged downstream of the multi-aperture arrangement 305 in the direction of the particle-optical beam path 11. This beam tube 151 is connected to a voltage supply which provides a beam tube voltage VT. From entry into the beam tube 151 and until the exit from the beam tube 151 through the beam exit opening 153, the first individual charged particle beams 3 have a constant kinetic energy ET. The kinetic energy ET of the first individual charged particle beams 3 or electron beams during the passage through the beam tube 151 is 20 keV, 30 keV or 35 keV, for example. The plurality of first individual particle beams 3 are imaged, and beam spots 5.1 to 5.3 are formed in the image plane 101 or object plane 101 via field lenses 333 and 103 and via the objective lens 102. In the example shown, the objective lens 102 is a magnetic lens with a winding 161 and a pole shoe 163 with a lower pole shoe segment 165, with the lower pole shoe segment 165 forming a gap in the axial direction for the magnetic field of the magnetic lens 163. A current I is provided during the operation of the winding 161 in order to create the focusing magnetic field (not depicted here). Other types of magnetic lenses are also possible, for example lenses with a radial gap for creating an immersion lens field or magnetic lenses with a plurality of windings and pole shoes. A beam splitter 400 is arranged above or partly integrated in the magnetic lens 102 and is configured to separate out the secondary electrons 9 or second individual charged particle beams 9 along the secondary particle-optical beam path 13 and guide these to the detection unit 200. An electrode 133 is provided below the lower pole shoe segment 165 and connected to a voltage supply such that a second voltage VE is provided at the electrode 133. The electrode 133 is embodied as a separate electrode in the example shown.

After leaving the beam tube 151, the plurality of first individual charged particle beams 3 are decelerated from the kinetic energy ET to the second kinetic energy EE. The voltage difference between VT and VE is responsible for the creation of the first electric field 135, which is depicted in FIG. 1 by two equipotential lines of the first electric field 135. The associated vectors of the electric field are substantially parallel to the propagation direction of the first individual charged particle beams 3 and create a decelerating force acting on the first individual charged particle beams 3. The first voltage VE is typically adapted so that the second kinetic energy EE lies in a range of less than 5 keV, less than 3 keV or even less than 2 keV. A third sample voltage VL is provided at the sample receiving pad 505, which serves to hold and contact the sample 7 during the operation of the multi-beam particle beam system 1, via the voltage supply unit 503. A second electric field 137 is created in accordance with the voltage difference between VL and VE; it is almost parallel to the propagation direction of the first individual charged particle beams 3 and exerts a decelerating force on the first individual charged particle beams 3 or the associated particles. The third or sample voltage VL is adapted such that the third kinetic energy or landing energy EL of the primary individual particle beams 3, for example electrons in the described example, lies in a range <800 eV, <300 eV or even <100 eV. The electric fields 135 and 137 both form a decelerating field serving to reduce the kinetic energy of the first individual charged particle beams 3 prior to incidence on the sample surface 25, which is arranged in the object plane 101. The first electric field 135 also forms an accelerating field for the second individual particle beams 9 or secondary electrons 9, which emanate from the sample 7 or wafer 7. The second electric field 137 forms an extraction field for extracting and accelerating secondary particles or secondary electrons from the sample 7 or wafer 7. The second electric field 137 is therefore also referred to as the extraction field 137.

The example depicted in FIG. 2 shows a two-stage decelerating field 135 and 137 and also an additional electrode 133. However, a different example might only provide for one decelerating field or extraction field 137, which is generated between, firstly, the beam exit opening 153 of the beam tube 151 and, secondly, the sample 7 arranged on the sample receiving pad 505. In this case, the exit opening 153 of the beam tube 151 plays the role of the electrode 133 for the extraction field 137.

The object illumination unit 100 of the multi-beam particle beam system 1 depicted in FIGS. 1 and 2 moreover comprises a collective deflection scanner 110 in the vicinity of a crossover region 108 of the individual charged particle beams 3. The collective deflection scanner 110 allows collective deflection of the first individual charged particle beams 3 into a scanning direction 143, with the scanning direction 143 being orthogonal to the propagation direction of the individual charged particle beams 3. The propagation direction of the first individual charged particle beams is in the positive z-direction in each of the examples described. Both the objective lens 102 and the collective scan deflector 110 are centered on an optical axis Z (not depicted here) of the multi-beam particle beam system 1 which is orthogonal to the sample surface 25 or wafer surface 25. The plurality of first individual charged particle beams 3, which form the beam spots 5 in accordance with a grid arrangement, are synchronously scanned over the wafer surface 25 or sample surface 25. According to an example, the grid arrangement of the beam spots 5 of the plurality of first individual charged particle beams 3 is a hexagonal grid of approximately 100 or more first individual charged particle beams 3, for example of 91 beams, 100 beams or even 300 or more beams. The beam spots 5 have a distance from one another of approximately 6 μm to 45 μm and a diameter of less than 5 nm, for example 3 nm, 2 nm or even less. According to an example, the size of a beam spot is approximately 3 nm and the pitch between adjacent beam spots is approximately 8 μm. A plurality of secondary electrons are created at each sampling position or scanning position of the first individual charged particle beams, and consequently created in the region of the beam spots 5, and each form a plurality of second individual charged particle beams 9 or charged secondary electron beams 9, to be precise in the same grid configuration as the beam spots 5. The intensity of the secondary electron beams 9 formed at each beam spot or illumination spot 5 depends on the intensity of the incident

first individual charged particle beams 3 illuminating the spot 5, on the material compositions 67, 69 and the topography of the object 7 under the respective illumination spot 5, and on the charge state of the sample 7 at the illumination spot 5. The plurality of second individual charged particle beams 9 are accelerated through the same electrostatic field between the objective lens 102 and the object surface 25 and are collected by the objective lens 102; the secondary beams 9 pass through the first collective scan deflector 110 in the opposite direction to the primary individual particle beams 3. The plurality of second individual charged particle beams 9 are deflected collectively via the collective scan deflector 110. The plurality of second individual charged particle beam 9 are then deflected via the beam splitter 400 in order to follow the second particle-optical beam path 13 to the detection unit 200. The plurality of second individual charged electron beams 9 in this case move in the opposite direction to the first individual charged particle beams 3, to be precise with the kinetic energy ES =ET-EL, and the beam splitter 400 is configured to separate the second particle-optical beam path 13 from the primary particle-optical beam path 11 via magnetic fields or via a combination of magnetic field and electrostatic field.

The detection unit 200 images the second individual particle beams 9 or secondary electron beams 9 on an image sensor 600, whereby a plurality of second charged image spots 15 are formed. The detector or image sensor 600 comprises a plurality of detection pixels or individual detectors. The intensity is detected separately for each of the second charged beam spots 15, and the property of the object surface 25 is recorded in high resolution and with a high throughput for a large image field of the object 7. For example, using a grid of 10×10 individual particle beams 3 with a pitch of 8 μm, it is possible to raster-scan an image field of approximately 88 μm×88 μm via an image scanning procedure via the collective scan deflector 110, with an image resolution being for example 2 nm or better. The image field is scanned with half the beam spot dimension, and hence with a total of 800 pixels per image line for each individual particle beam 3 such that the image field created, which is created via 100 individual particle beams 3, comprises approximately 6.4 gigapixels. The digital image data are collected via the controller 800. Details relating to the image data collection and image data processing, for example using parallel data processing, are described in the international patent application WO 2020 151 904 A2 and in the U.S. Pat. No. 9,536,702 B2, the content of each is fully incorporated by reference in the present patent application.

The detection unit 200 moreover comprises at least one second collective scan deflector 222, which is connected to the scan deflector controller module 860. The scan deflector controller module 860 is configured to compensate a deviation in the deflection force of the first collective scan deflector 110 in the common particle-optical beam path such that the positions of the second individual particle beams 9 upon incidence on the image sensor 600, and consequently the beam spots 15, are kept constant in terms of position. The difference in the collective deflection in accordance with the first collective scan deflector 110 arises due to the different kinetic energies ET of the first individual particle beams 3 in comparison with the kinetic energy ES of the second individual particle beams 9. Moreover, the multi-beam particle beam system 1 may optionally comprise a retractable monitoring system 230. Monitoring systems and monitoring methods for detecting charging effects on charged samples are described in detail in the patent applications PCT/EP2022/061042 and DE 10 2022114923.4, each of which is fully incorporated by reference in the present patent application. The detection unit 200 will be described in detail below.

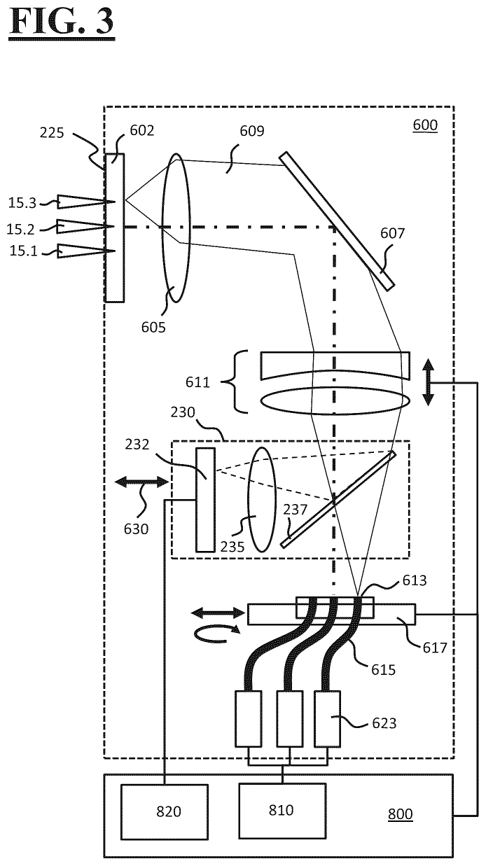

The image sensor 600 is configured by an arrangement or array of detection regions arranged in a pattern which is compatible with or corresponds to the grid arrangement of the second individual particle beams which are focused on the image sensor 600 via the detection unit 200. This enables the detection of each second individual particle beam 9, independently of the remaining second individual particle beams 9, upon incidence on the image sensor 600. The image sensor 600 depicted in FIG. 1 can be an electron-sensitive detection array, for example a CMOS detector or a CCD sensor. Such an electron-sensitive detection array may comprise an electron-photon conversion unit, for example a scintillation element or an array or grid of scintillation elements. In another exemplary embodiment, the image sensor 600 can be designed as an electron-photon conversion unit which is arranged in the focal plane of the second individual particle beams 9 or beam spots 15 formed. In this embodiment variant, depicted by way of example in FIG. 3, the image sensor 600 may moreover comprise an optical relay system comprising converging lenses 605 and a zoom lens 611 for imaging and guiding the photons arising at the points of incidence 15 via the electron-photon conversion unit 602 to special photon detection elements 623, for example a plurality of photomultipliers or avalanche photodiodes. For example, such an image sensor 600 is disclosed in U.S. Pat. No. 9,536,702 B2, which was cited above and is fully incorporated by reference in the present patent application. In the example described, the image sensor 600 has moreover been provided with an optionally retractable monitoring system 230 which comprises a beam splitter mirror 237, an imaging lens 235 and a high-resolution CMOS sensor 232.

Optionally, the sample stage 500 is not moved while an image field is recorded by scanning the sample 7 via the plurality of first individual charged particle beams 3; the sample stage 500 is moved following the recording of an image field, and the next image field is recorded. According to an alternative implementation, the sample stage 500 is moved continuously in a second direction while an image is recorded by scanning the plurality of individual charged particle beams 3 in a first direction using the collective scan deflector 110. The movement of the sample stage 500 and the position of the sample stage 500 are monitored and controlled via known sensor systems, for example using laser interferometers, grating interferometers, confocal microlens arrays or the like.

While an image is recorded, the controller 800 is configured to trigger the image sensor 600 to record a plurality of temporally corresponding intensity signals from the plurality of second individual particle beams 9 at predetermined time intervals, and the digital image of an image field is collected and stitched together from all sampling positions or scan positions of the plurality of first individual particle beams 3.

The controller 800 of the multi-beam particle beam system 1 moreover comprises an image controller module 810 configured to receive a data stream from the image sensor 600 and create a digital image of the surface of the sample 7 during operation. The controller moreover comprises a secondary path controller module 840 configured to control the detection unit 200. The controller 800 moreover comprises a primary path controller module 830 configured to control the elements of the object illumination unit 100. The controller 800 moreover comprises a sample stage controller module 850 configured to control the positioning and alignment of the sample stage and control the provision of the voltage via the voltage provision module 503. The controller 800 moreover comprises a scan deflector controller module 860 configured to control a scanning operation or scanning procedure via the first collective scan deflector 110 and via the second deflection system 222. Moreover, the controller 800 comprises a processor 880 for the controller, the processor being configured to control inspection tasks for the samples 7 and moreover configured to control the modules 810, 820, 830, 840, 850, 860 and a memory 890 for storing software, work instructions and image data. The processor 880 for the controller 800 is moreover connected to a user interface IX for exchanging data, work instructions, software or user interactions.

The controller 800 of the multi-beam particle beam system 1 moreover comprises a contrast controller module 870 which is connected to the processor 880 for the controller 800. The contrast controller module 870 is configured to receive instructions from the processor 880 for the controller, for the purpose of compensating charging effects while the second individual particle beams 9 are imaged on the image sensor 600. The contrast controller module 870 is connected to a sensor controller module 820 which in turn is connected to the monitoring system 230.

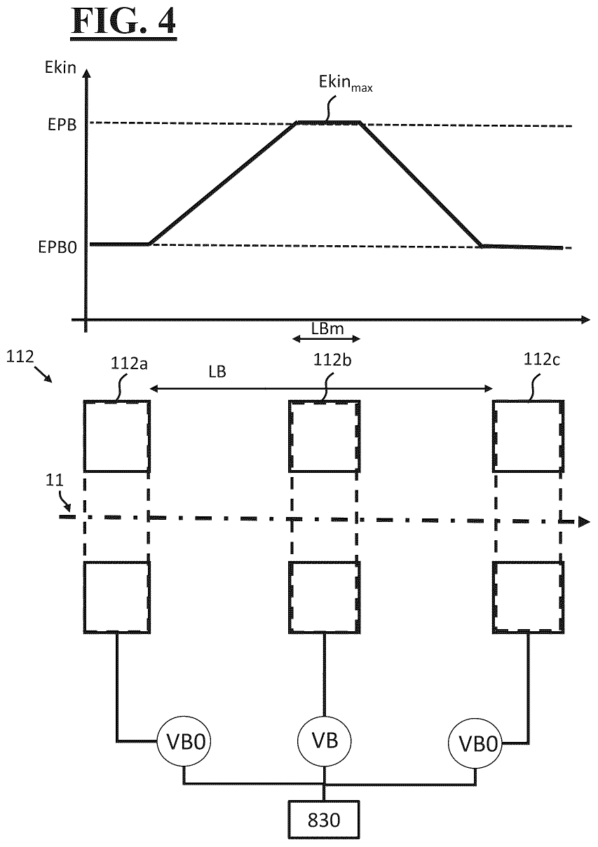

According to the disclosure, it is now possible to integrate an electrostatic booster lens 112 in the multi-beam particle beam system 1 described above by way of example. In this case, the electrostatic booster lens 112 is arranged in the crossover region 108 of the first individual charged particle beams 3 in the primary particle-optical beam path 11. In turn, this crossover region 108 is situated in the upper focal plane of the objective lens 102. The controller 800 or one of its modules, for example the primary path controller module 830, is configured to provide a booster high voltage VB at the electrostatic booster lens 112 via a voltage provision unit (not explicitly illustrated in FIGS. 1 to 3), in such a way that the first individual charged particle beams 3 pass through the crossover region 108 with a section-wise significantly increased kinetic energy such that aberrations on account of a Coulomb interaction between the first individual charged particle beams 3 within the crossover region 108 are reduced. The position of the electrostatic booster lens 112 is depicted schematically in FIG. 1 via the arrow, with details of the electrostatic booster lens 112 itself not being depicted explicitly in FIG. 1. Instead, FIG. 4 schematically shows an electrostatic booster lens 112 and the control thereof, and also its influence on the kinetic energy of the charged particles traversing it:

FIG. 4, bottom, initially depicts the electrostatic booster lens 112, which is substantially in the form of an Einzel lens in the example shown. In this case, the Einzel lens comprises a first (upper) electrode 112a, a second (central) electrode 112b and a third (lower) electrode 112c. In this case, the electrodes 112a, 112b and 112c might be designed, by way of example, as thin plates with a central opening and thus realize tube lenses or tube lens sections. In this case, the central openings are arranged centrally on the particle-optical axis Z or centrally in relation to the first particle-optical beam path 11. Voltage can be applied to the first electrode 112a, the second electrode 112b and the third electrode 112c on an individual basis. In the example shown, the voltage provision is controlled in each case via the primary path controller module 830. To this end, a voltage VB0 is provided at the first electrode 112a of the electrostatic booster lens 112. In the example shown, the same voltage VB0 is also provided at the third electrode 112c of the electrostatic booster lens 112. By contrast, a high voltage VB is provided at the second electrode 112b. For example, the voltage VB0 provided can be a low voltage. The low voltage VB0 can also be 0 V, i.e. ground potential. For example, the booster high voltage VB can be ≥10 kV or ≥15 kV. FIG. 4 merely shows the principle in this respect. As a result of the potential difference between the first electrode 112a and the second electrode 112b (and in the case of appropriate polarity), the first individual charged particle beams 3 are accelerated in the region between the electrodes 112a, 112b, and their kinetic energy is increased significantly. The first individual charged particle beams 3 then move with the maximum kinetic energy Ekinₘₐₓ in the interior of the tube lens section or in the interior of the central electrode 112b. Owing to the potential difference between the electrodes 112b and 112c, the charged particles or the first individual charged particle beams 3 are decelerated significantly following their emergence from the central electrode 112b, down to the original kinetic energy EPB0 which the charged particles or particle beams 3 also already had upon entrance into the accelerating field of the electrostatic booster lens 112. For example, this kinetic energy EPB0 can be identical to the kinetic energy ET depicted schematically in FIG. 2 for the primary path. If the electrostatic booster lens 112 is designed precisely as an Einzel lens, then the kinetic energies of the first individual charged particle beams 3 upon entrance into the electrostatic booster lens 112 and upon exit from the electrostatic booster lens 112 are exactly the same in terms of magnitude. As a result, the kinetic energy is significantly increased section-wise, to be precise only section-wise, in the crossover region 108.

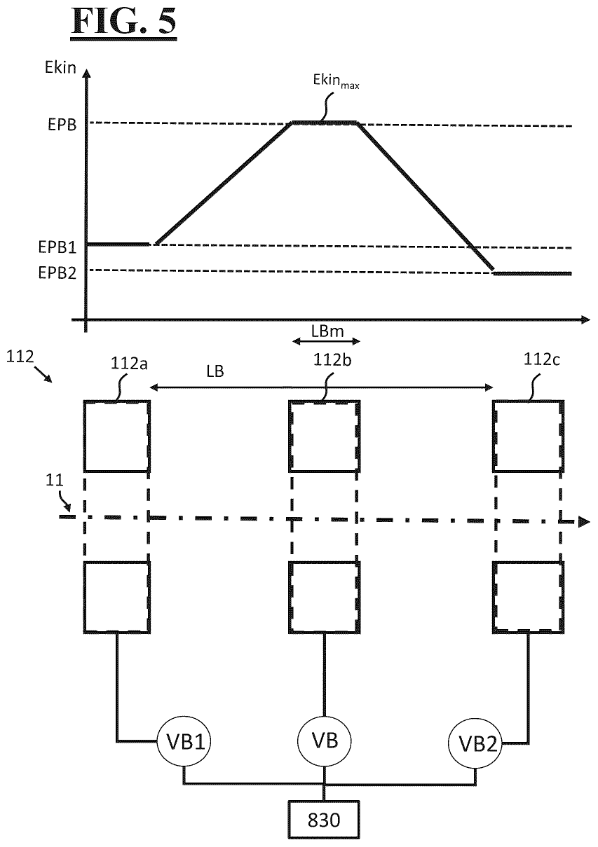

FIG. 5 shows a slight modification of the example depicted in FIG. 4: In this case, the electrostatic booster lens 112 is designed not precisely as an Einzel lens but only substantially as an Einzel lens 112. Like in the preceding example according to FIG. 4, a high voltage or a booster high-voltage potential VB is applied to the second electrode 112b. However, according to FIG. 5, the two low-voltage potentials at the first electrode 112a and at the third electrode 112c of the electrostatic booster lens 112 have been chosen not to be identical but slightly different. In the example shown, a low-voltage potential VB1 is applied to the first electrode 112a, and a low-voltage potential VB2 is applied to the third electrode 112c. Thus, the kinetic energy of the charged particles or first individual charged particle beams 3 upon entrance into the electrostatic booster lens 112 differs slightly to that upon exit from the electrostatic booster lens 112. Specifically, the kinetic energy upon entrance in FIG. 5, being EPB1, is slightly higher than upon exit, with the kinetic energy then only being EPB2, where EPB1>EPB2. However, the maximum kinetic energy in the interior of the central electrode 112b is identical in both cases. In theory, it is also possible for the kinetic energy EPB2 upon exit from the electrostatic booster lens 112 to be greater than upon entrance into the electrostatic booster lens 112, and so the following applies: EPB2>EPB1. In this context, attention is drawn to the fact that the kinetic energy in the diagram portion of FIG. 5 is plotted only schematically and not true to scale.

As a result of the kinetic energy of the first individual particle beams 3 being significantly increased in a targeted manner in the crossover region 108, and hence only section-wise, it is not necessary in comparison with the prior art to modify the voltage applied to the other elements of the multi-beam particle beam system 1. For example, there is no need to further increase, in terms of absolute value, a high voltage applied to the particle source 301, and nor is it necessary to do this for the high voltage provided at the sample stage 500 or, via the current voltage supply 503, at the sample receiving pad 505. Instead, the first high voltage V1 provided at the particle source via a voltage provision unit may, in terms of absolute value, satisfy the following relation: 20 kV≤V1≤40 kV, such as 25 kV≤V1≤35 kV. Moreover, in terms of absolute value, the following relation may apply to the second high voltage V2 provided at the sample: 20 kV≤V2≤40 kV, such as 25 kV≤V2≤35 kV. Moreover, it is possible to provide no more than a low voltage Vm at the multi-aperture arrangement 305 or at the multi-beam generator 305 (also referred to as a micro-optical unit), even when a booster lens 112 is implemented. A low voltage Vm which, in terms of absolute value, can satisfy the following relation can be provided at the multi-aperture arrangement 305:0 V≤Vm≤100 V, such as 0 V, i.e. ground potential. In that case, it is also possible to supply ground potential or at least only a low-voltage potential to the beam tube arrangement 151.

This allows, in the particle-optical beam path 11 between the particle source 301 and the sample 7, the first individual particle beams 3 to have their maximum kinetic energy Ekinₘₐₓ in the region of the booster lens 112, and hence in the crossover region 108, wherein, in terms of absolute value, the following relation applies to a maximum electric potential growth ΔVB brought about by the electrostatic booster lens 112: ΔVB≥10 kV, such as ΔVB≥15 kV. For example, the high voltage VB at the electrostatic booster lens 112 or at the second (central) electrode 112b can be VB≥10 kV, such as VB≥15 kV.

In this case, a length LB of the electrostatic booster lens 112 along the particle-optical axis Z is very short, and for example the following relation may apply: 2 mm≤LB≤10 mm. The length LB is plotted by way of example in FIGS. 4 and 5 and is identical to the length in the direction of the particle-optical beam path 11 in the primary path in which the electrostatic booster lens 112 is effective overall. In this case, the length LB substantially corresponds to the path between the electrodes or counter electrodes of the electrostatic booster lens. Moreover, according to one example, the following relation applies to a length LBm of the central electrode 112b: 1.5 mm≤LBm≤4.5 mm.

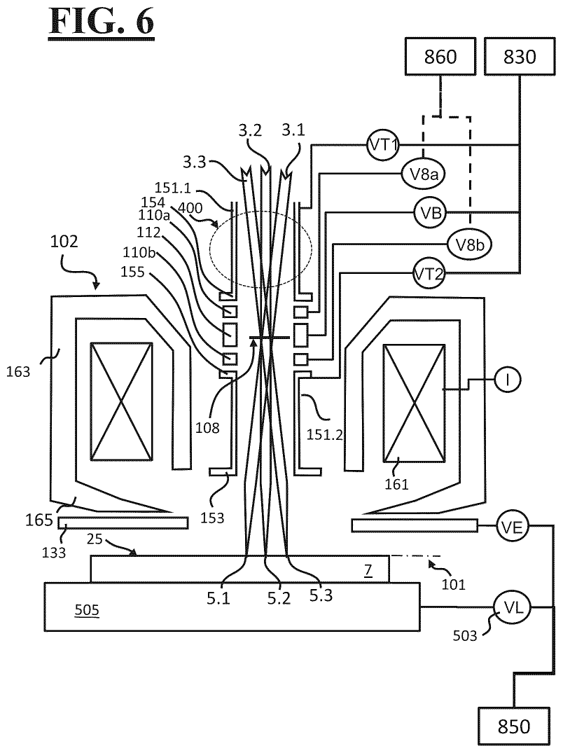

FIG. 6 schematically shows an arrangement of an electrostatic booster lens 112 in a multi-beam particle beam system 1, for example in an inspection system or in a lithography system. As already explained in the context of FIG. 1, the collective scan deflector 110 serving to raster-scan the sample 7 is also arranged in the vicinity of the crossover region 108. This collective scan deflector 110 comprises an upper scan deflector 110a and a lower scan deflector 110b. The electrostatic booster lens 112 or its second (central) electrode 112b is now arranged between this upper scan deflector 110a and the lower scan deflector 110b. In this case, the upper scan deflector 110a, the lower scan deflector 110b and the central electrode 112b of the booster lens 112 are situated within a beam tube interruption: In the exemplary embodiment depicted in FIG. 6, the beam tube 151 is divided into a first (upper) beam tube section 151.1 and a second (lower) beam tube section 151.2. In this case, a DC voltage VT1 is applied to the first (upper) beam tube section 151.1. A DC voltage VT2 is applied to the second (lower) beam tube section 151.2. The provision of the DC voltages VT1 and VT2 is controlled by the primary path controller module 830. The voltages VT1 and VT2 might differ, but they might also be identical. Together with the electrode 112b of the electrostatic booster lens 112, to which a high voltage or a high-voltage potential VB has been applied, the overall design of the electrostatic booster lens 112 thus substantially corresponds to that of an Einzel lens. In other words, the first electrode 112a of the electrostatic booster lens 112 is realized by the exit region 154 of the first beam tube section 151.1, and the third electrode 112c of the electrostatic booster lens 112 is realized by the entrance region 155 into the second beam tube section 151.2.

According to an alternative exemplary embodiment, it would also be possible for an offset voltage VB to be applied to one of the scan deflectors 110a, 110b (not depicted here). In that case, the other scan deflector 110b, 110a and one of the beam tube sections 154, 155 can form the counter electrodes of the booster lens 112. Very generally, at least one of the electrodes 112a, 112b, 112c of the electrostatic booster lens 112 can be realized via an offset potential at a multi-pole electrode, for example at one of the scan deflectors 110a, 110b.

While the electrostatic booster lens 112 or the voltages VT1, VB and VT2 applied thereto are provided or controlled via the primary path controller module 830, the voltage provided at the collective deflection scanner 110 is provided or controlled via the scan deflector controller module 860. In the example illustrated, the upper scan deflector 110a is in the form of an electrostatic octupole electrode, wherein the voltage V8a is applied to the octupole electrode. In this case, an individual voltage can be applied to each of the eight electrodes of the octupole. A corresponding statement applies to the lower scan deflector 110b embodied as an electric octupole electrode, wherein an individually adjustable voltage can be applied to each of the eight electrodes; this is depicted symbolically by the voltage V8b in FIG. 6.

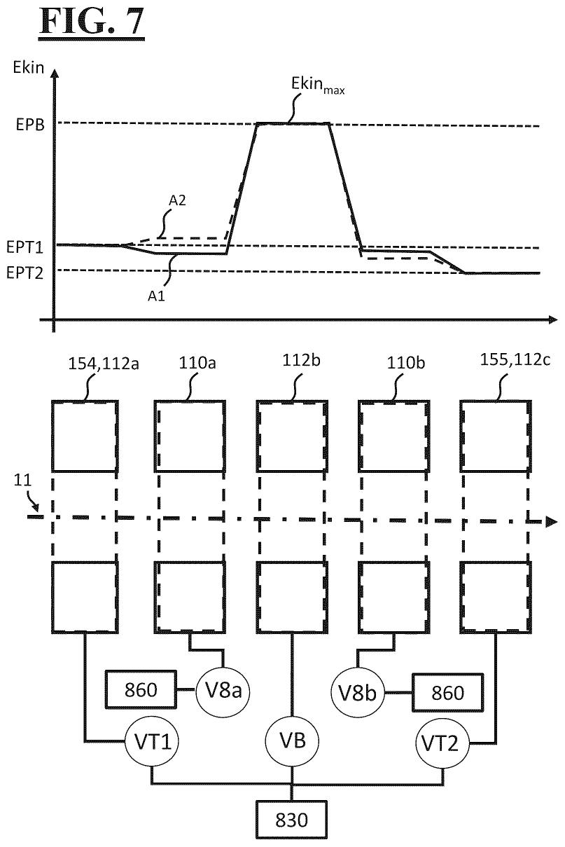

FIG. 7 schematically shows an electrostatic booster lens 112 and the control thereof, and also its influence on the kinetic energy of the charged particles traversing it, in the case of an arrangement of the booster lens 112 in accordance with FIG. 6. The electrostatic booster lens 112 comprises the beam tube exit region 154 of the first (upper) beam tube section 151.1 as first electrode and the beam tube entrance region 155 of the second (lower) beam tube section 151.2 as third electrode. The second electrode, i.e. the central electrode 112b of the electrostatic booster lens 112, is provided centrally. This forms an Einzel lens, to the electrodes of which the voltages of VT1, VB and VT2 are applied. The voltage VB is a high-voltage potential. The applied voltages VT1, VB and VT2 provided via the primary path controller module 830 are static voltages. By contrast, the upper scan deflector 110a and the lower scan deflector 110b of the collective scan deflector 110 are controlled dynamically. The specific control of the multi-pole electrodes, for example the octupole electrodes, depends on the scanning position of the first individual particle beams 3 on the sample. Thus, this also lends itself to controlling the collective scan deflector 110 via a separate module, via the scan deflector controller module 860 in the example shown.

As already mentioned, the voltage applied to the central electrode 112b of the electrostatic booster lens 112 is a high voltage. By contrast, voltages provided at the multi-pole electrodes 110a, 110b of the collective scan deflector 110 are low voltages. For example, they are approximately 50 V.

The control of the total of five electrodes in FIG. 7 is also reflected in the associated diagram of the kinetic energy of the charged particles which form the first individual charged particle beams 3: The diagram in FIG. 7 in each case plots the kinetic energies for two different controls of the upper scan deflector 110a and lower scan deflector 110b. The solid line A1 shows the profile of the kinetic energy in the case of a first control of the collective scan deflector 110, and the dashed line A2 shows the kinetic energy in the case of a second control of the collective scan deflector 110. In the case of the first control A1, the kinetic energy of the charged particles is slightly reduced, the particles thus are slightly decelerated, in a region between the first electrode 112a of the booster lens 112 and the upper scan deflector 110a. Following the traversal through the upper scan deflector 110a, there is a strong, boosted increase in the kinetic energy up to the entrance into the central electrode 112b of the electrostatic booster lens 112. The central electrode 112b is then traversed with the maximum kinetic energy Ekinₘₐₓ or the kinetic energy EPB. Then, the kinetic energy is reduced drastically between the central electrode 112b of the electrostatic booster lens 112 and the lower scan deflector 110b. Then, there is another slight reduction in the kinetic energy between the exit from the lower scan deflector 110b and the entrance into the beam tube entrance region 155 or the third electrode 112c of the electrostatic booster lens 112.

In the case of the second depicted control of the collective scan deflector 110, there initially is a slight increase in the kinetic energy between the first electrode 112a or the beam tube exit region 154, before the significant increase in speed or the maximum kinetic energy Ekinₘₐₓ is then attained between the upper deflector 110a and the central electrode 112b of the electrostatic booster lens 112. This maximum kinetic energy during the second control of the collective scan deflector 110 is substantially identical to the kinetic energy during the control of the collective scan deflector in the first type of control A1. The kinetic energy subsequently reduces very significantly, to be precise to an even slightly lower level than in the first type of control A1 of the collective scan deflector 110 in the event of the second type of control A2. Then, there is a further, weak reduction in the kinetic energy between the lower scan deflector 110b and the beam tube entrance region 155 serving as the third electrode 112c of the electrostatic booster lens 112. Despite the slight potential differences or differences in kinetic energy upon entrance into and exit from the electrostatic booster lens 112 overall, the design of the electrostatic booster lens in the example depicted in FIG. 7 is also substantially that of an Einzel lens.

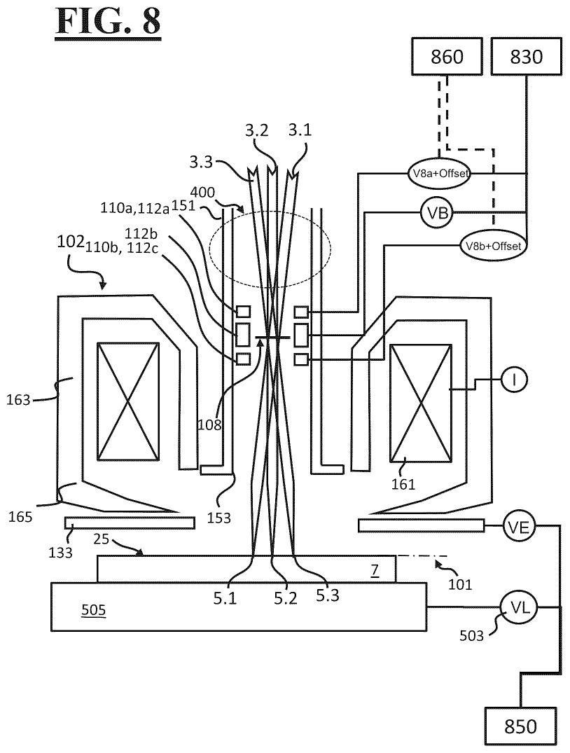

FIG. 8 schematically shows a further arrangement of an electrostatic booster lens 112 in a multi-beam particle beam system 1. The multi-beam particle beam system can be e.g. an inspection system or a lithography system. In the example depicted in FIG. 8, the lens effect of the electrostatic booster lens 112 is realized at least in part via an offset voltage at a multi-pole electrode. Specifically, the collective deflection scanner is combined with the counter electrodes (i.e. the first and the third electrode of the electrostatic booster lens 112) in the exemplary embodiment shown in FIG. 8: In principle, all individual electrodes can be controlled individually in a multi-pole electrode. This is accordingly the case for the upper scan deflector 110a and the lower scan deflector 110b. Moreover, there is the option of applying the same voltage as offset to all individual electrodes of the multi-pole electrode. As a result, the multi-pole electrode also has a round lens component and a round lens effect can be obtained in addition to the collective beam deflection.

In the example shown, the multi-beam particle beam system 1 comprises a beam tube arrangement 151 which comprises a beam tube extension in the example shown, i.e. a section projecting into the objective lens 102. The electrostatic booster lens 112 is arranged within this beam tube extension. This example then does not envisage a beam tube interruption in the region of the crossover region 108.

A statically provided booster high voltage VB is once again applied to the central electrode 112b of the electrostatic booster lens 112. The voltage V8a already provided at the upper scan deflector 110a is provided dynamically and overlaid with a static offset. Accordingly, the voltage V8b at the lower scan deflector 110b is also provided dynamically and overlaid with a static offset voltage. The two offset voltages can be identical but might also differ from one another.

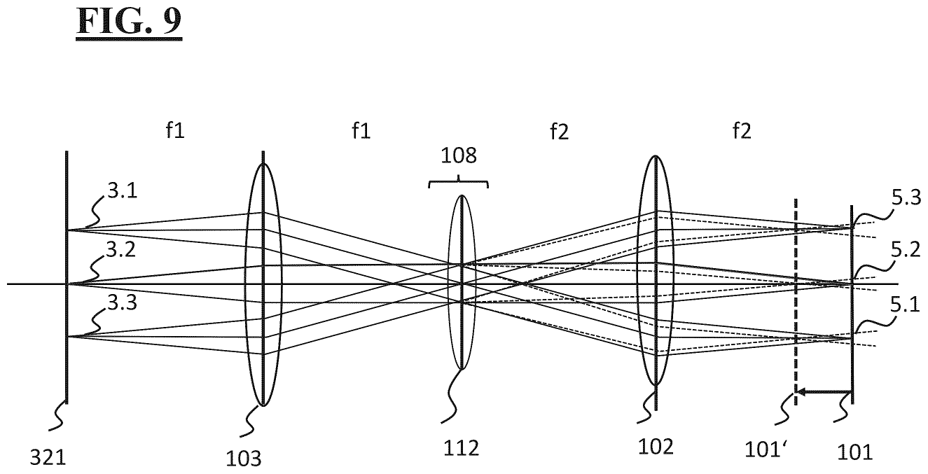

FIG. 9 schematically shows a 4f system with an electrostatic booster lens 112 in a crossover region 108, and the influence of the electrostatic booster lens on the particle-optical beam path. A 4f system is a schematic reproduction of an imaging system. Fundamentally, the 4f system comprises a first lens with a focal length f1 and a second lens with a focal length f2. The magnification of the system is M=f2/f1. The intermediate image plane between the two partial systems is the plane in which the chief rays of the individual particle beams move parallel to one another (this cannot be identified in FIG. 9 with the simplified representation). If a stop is arranged in the intermediate image plane in the crossover region 108 or, to be precise, in the crossover plane 108, then this does not modify the telecentric properties of the imaging system.

Transferred to the multi-beam particle beam system 1, this means the following: The first individual particle beams 3 is telecentric upon incidence on the object plane 101 for inspection purposes or illumination purposes with great uniformity. The second lens in the 4f system thus corresponds to the objective lens 102. Thus, for telecentric imaging, the upper focal plane of the objective lens 102 coincides with the crossover region 108. The electrostatic booster lens 112 is therefore situated in the upper focal plane of the objective lens 102 or, expressed differently, in the crossover region 108. For as long as the electrostatic booster lens 112 or, when designed as an Einzel lens, its central electrode 112b is situated within the crossover region 108, the provision of the electrostatic booster lens 112 does not modify the telecentric properties of the first individual particle beams 3 upon incidence on the object plane 101.

The intermediate image plane 321 and a field lens 103 are also depicted in the example illustrated in FIG. 9. In the example shown, the first individual particle beams 3 are parallel to one another in the intermediate image plane 321. However, this need not be the case.

If the excitation of the electrostatic booster lens 112 now is varied, then this changes a working distance WD or the position of the object plane 101 to the position of the object plane 101′. A first setting mechanism which is controlled via the controller 800 such that the booster high voltage VB applied to the electrostatic booster lens 112 is modified can be provided for this variation of the electrostatic booster lens 112. In addition to that or in an alternative, this modified setting of the electrostatic booster lens 112 can also modify the numerical aperture NA of the first individual particle beams 3 upon incidence on the object plane 101, 101′.

Moreover, a second setting mechanism which differs from the first setting mechanism is provided according to an embodiment of the disclosure. In that case, the controller 800 is configured to control the second setting mechanism such that the modified working distance WD of the first individual particle beams 3 is corrected or modified and/or such that the modified numerical aperture NA of the first individual particle beams 3 upon incidence on the object plane 101 is corrected or modified. Expressed in general terms, the multi-beam particle beam system 1 comprises a further degree of freedom in the case of a variable static booster high voltage VB applied to the electrostatic booster lens 112. As a result, modifications of other imaging parameters caused by varying the refractive power of the electrostatic booster lens 112 can be corrected accordingly. However, for as long as the electrostatic booster lens 112 is substantially situated within the crossover region 108, neither the magnification nor the telecentricity is changed even in the event of a modified control of the electrostatic booster lens 112. In this context, the 4f system according to FIG. 9 is fundamentally maintained from a geometric point of view.

To thus keep the overall system telecentric, both the objective lens focal length f2 and the field lens focal length f1 can be varied simultaneously in the system according to an embodiment variant of the disclosure. The effect on the imaging scale is only very small and can be tolerated. Even if the stop plane is displaced slightly in the region of the electrostatic booster lens 112, the crossover region nevertheless remains within the electrostatic booster lens 112. In FIG. 9, the modified position of the object plane 101 is indicated by the dashed beam path.

A change in the refractive power of the objective lens 102 can be realized in different ways: According to a first embodiment variant, the excitation or a current I of the objective lens can be varied (cf. FIG. 2). In addition to that or in an alternative, a variation in the refractive power of the objective lens 102 can be caused by a modified control of the collective scan deflector 110 or of at least one of its deflectors 110a, 110b. In addition to that or in an alternative, a modified voltage, for example a modified low voltage VT2, can be applied to the second (lower) beam tube section 151.2 when the beam tube arrangement 151 is divided into a first (upper) beam tube section 151.1 and the second (lower) beam tube section 151.2. The second, lower beam tube section 151.2 is situated within the magnetic field of the objective lens 102, and so a modified voltage at the lower beam tube section 151.2 results in a changed speed of the charged particles of the first individual particle beams 3 within the magnetic field of the objective lens 102, in turn modifying the refractive power of the objective lens 102.

In addition to that or in an alternative, an electrostatic correction element can be arranged in the magnetic field of the objective lens 102.

The variation possibilities described for the modified refractive power of the objective lens 102 can be realized via a second setting mechanism (not depicted here), which is controlled via the controller 800 or else a constituent part of the controller 800.

According to an alternative embodiment variant of the disclosure, the refractive power of the objective lens 102 remains unmodified, and only the refractive power of the field lens 103 is adapted. This modifies the input telecentricity of the first individual charged particle beams 3.1, 3.2, 3.3 in the intermediate image plane 321 and consequently upon entrance into the 4f system according to FIG. 9. The input telecentricity can be modified or adapted via a second field lens 333 (see FIG. 1) or an alternative telecentricity setting mechanism. Overall, the 4f system remains telecentric even in this embodiment variant, or the first individual particle beams 3 are incident on the object plane 101 in telecentric fashion.

In the two embodiment variants described in detail above, the extraction field between the electrode 133 and the sample or the wafer 7 can remain unmodified.

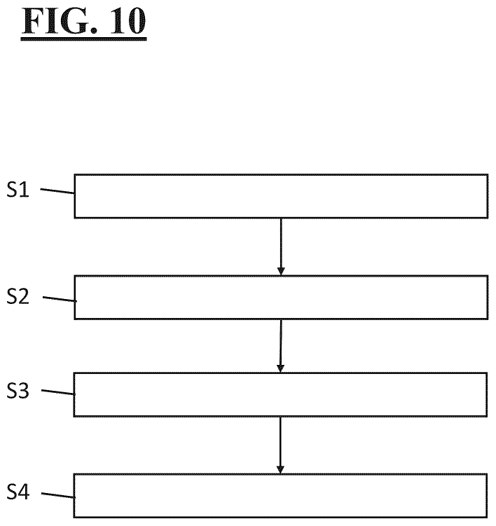

FIG. 10 schematically shows a flowchart of a method according to the disclosure for operating a multi-beam particle beam system 1 as described above in several embodiment variants. According to a first method step S1, a multi-beam particle beam system 1 with a crossover region 108 of first individual charged particle beams 3 in the illumination beam path 11 in an upper focal plane of an objective lens 102 is provided.

In a second method step S2, the kinetic energy of the first individual particle beams 3 is increased section-wise in the crossover region 108 for the purpose of significantly reducing the Coulomb interaction between the first individual charged particle beams 3.

According to a third method step S3, the maximum kinetic energy of the first individual particle beams 3 is modified in the crossover region, whereby at least one imaging parameter of the multi-beam particle beam system 1 is modified upon incidence of the first individual particle beams 3 on the object plane 101. For example, this can be the working distance WD or the refractive power of the objective lens 102; in addition to that or in an alternative, this may also relate to the numerical aperture NA. Despite modification of the maximum kinetic energy of the first individual particle beams 3 in the crossover region 108, other imaging parameters do not change or at least do not change significantly; for example, the telecentricity upon incidence of the first individual particle beams on the object plane 101 is maintained.

According to a further method step S4, the at least one modified imaging parameter is corrected, for example the modified working distance WD and/or the modified numerical aperture NA.

The described method steps of the method according to the disclosure can be realized by the above-described features of the multi-beam particle beam system 1 and for example by its particle-optical elements such as the electrostatic booster lens 112 and the described controller 800.

Overall, the exemplary embodiments described in the part relating to the drawings should not be construed as limiting for the disclosure but instead merely serve for the better understanding of the disclosure.

The disclosure relates to a multi-beam particle beam system 1 having a better resolution and a faster recording speed. To this end, an electrostatic booster lens 112 is arranged in an upper focal plane of the objective lens 102 level with the crossover region 108 of the primary particle beams 3. The electrostatic booster lens 112 is used to significantly increase the kinetic energy of the primary beams 3 in the crossover region 108 in a targeted manner, which is why the Coulomb interaction between the charged particles 3 is reduced.

### LIST OF REFERENCE SIGNS

1 Multi-beam particle beam system
3 Primary particle beams (first individual particle beams)
5 Beam spots, incidence locations of the first individual particle beams
7 Object, sample
9 Secondary particle beams (second individual particle beams)
13 Secondary particle-optical beam path
15 Beam spots, incidence locations of the second individual particle beams
25 Surface of the object or the sample
67 First material composition
69 Second material composition
100 Object illumination unit
101 Object plane
102 Objective lens
103 Field lens
108 Crossover region
110 Collective scan deflector (primary path)
110a Upper scan deflector
110b Lower scan deflector
112 Electrostatic booster lens
112a First electrode of the electrostatic booster lens
112b Second electrode of the electrostatic booster lens
112c Third electrode of the electrostatic booster lens
133 Electrode
135 First electric field
137 Second electric field
151 Beam tube
151.1 First (upper) beam tube section
151.2 Second (lower) beam tube section
153 Beam exit opening
154 Beam tube exit region
155 Beam tube entrance region
161 Winding
163 Pole shoe
165 Lower pole shoe segment
200 Detection unit
222 Second collective deflection scanner (secondary path)
225 Image plane for second individual particle beams
230 Monitoring system
232 High-resolution sensor
235 Imaging lens
237 Beam splitter mirror
300 Beam creation apparatus
301 Particle source
303 Collimation lens system, condenser lens system
304 Filter plate
305 Multi-beam generator, multi-aperture arrangement
306 Multi-aperture plates
309 Primary particle beam
321 Intermediate image plane
331 First field lens
333 Second field lens
400 Beam splitter
500 Sample stage
503 Sample voltage supply
505 Sample receiving pad
600 Image sensor
602 Electron-to-photon converter, scintillator plate
605 Converging lens
609 Light ray
611 Zoom lens
613 Light entrance face
615 Optical fiber
617 Motor, rotary motor
623 Detection element
630 Movement direction
800 Controller
810 Image controller module
820 Sensor controller module
830 Primary path controller module
840 Secondary path controller module
850 Sample stage controller module
860 Scan deflector controller module
870 Contrast controller module
880 Processor for the controller
890 Memory
IX User interface

1. A multi-beam particle beam system, comprising:
a particle source configured to emit a charged particle beam;
a multi-aperture arrangement comprising an aperture plate which comprises a multiplicity of passage openings, the multi-aperture arrangement is configured to generate a first field of a plurality of first individual charged particle beams from the charged particle beam;
a first particle-optical unit having a first particle-optical beam path, the first particle-optical unit configured to image the first individual particle beams onto a sample surface in an object plane of the multi-beam system so that the first individual particle beams are incident on the sample surface at incidence locations which define a second field;
a magnetic and/or electrostatic objective lens configured to have the first individual particle beams pass therethrough, a crossover region of the first particle-optical beam path of the first individual charged particle beams being disposed in a region of an upper focal plane of the objective lens;
an electrostatic booster lens in a region of this crossover region;
a voltage provision unit; and
a controller configured to control the multi-beam particle beam system,
wherein the controller is configured to provide a booster high voltage at the electrostatic booster lens via the voltage provision unit so that the first individual charged particle beams pass through the crossover region section-wise with a substantially increased kinetic energy to reduce aberrations due to Coulomb interaction between the individual particle beams within the crossover region.

2. The multi-beam particle beam system of claim 1, wherein:
along the particle-optical beam path between the particle source and the sample, the first individual particle beams have their maximum kinetic energy in the crossover region; and
a maximum electric potential growth due to the booster lens is at least 10 kilo Volts.

3. The multi-beam particle beam system of claim 1, wherein the controller is configured to provide:
a first high voltage at the particle source via the voltage provision unit;
at most a low voltage at the multi-aperture arrangement via the voltage provision unit; and
a second high voltage at the sample via the voltage provision unit.

4. The multi-beam particle beam system of claim 3, wherein:
the first and second high voltages have the same sign;
an absolute value of the first high voltage at the particle source is from 20 kilo Volts (kV) to 40 kV;
an absolute value of the second high voltage at the sample stage is from 20 kV to 40 kV; and
an absolute value the low voltage at the multi-aperture arrangement is from zero Volts (V) to 100 V.

5. The multi-beam particle beam system of claim 4, wherein:
the booster high voltage has a different sign to the first and the second high voltage; and
an absolute value of the booster high voltage at the electrostatic booster lens is at least 10 kV.

6. The multi-beam particle beam system of claim 1, wherein:
a length of the electrostatic booster lens along the particle-optical axis is from two millimeters to 10 millimeters; and/or
a length of a central electrode of the electrostatic booster lens is from 1.5 millimeters to 4.5 millimeters.

7. The multi-beam particle beam system of claim 1, wherein the electrostatic booster lens comprises as an Einzel lens.

8. The multi-beam particle beam system of claim 1, wherein a the multi-beam particle system is configured so that a lens effect of the electrostatic booster lens is realized at least in part via an offset voltage at a multi-pole electrode.

9. The multi-beam particle beam system of claim 1, comprising a beam tube arrangement, wherein:
the multi-beam particle beam system is configured so that the first individual particle beams are guided at least section-wise within the beam tube arrangement;
the beam tube arrangement comprises a beam tube extension extending into the objective lens; and
the electrostatic booster lens is in this beam tube extension.

10. The multi-beam particle beam system of claim 1, comprising a beam tube arrangement, wherein:
the multi-beam particle beam system is configured so that the first individual particle beams are guided at least section-wise within the beam tube arrangement;
the beam tube arrangement comprises a beam tube interruption in the region of the crossover region;
the beam tube arrangement comprises a first beam tube section and a second beam tube section;
the first beam tube section defines an upper electrode of the electrostatic booster lens;
a central electrode of the electrostatic booster lens is within the beam tube interruption; and
the second beam tube section defines a lower electrode of the electrostatic booster lens.

11. The multi-beam particle beam system of claim 1, further comprising a collective scan deflector comprising upper and lower deflection units, wherein:
the upper deflection unit is in an upper portion of the crossover region;
the lower deflection unit is in a lower portion of the crossover region; and
a central electrode of the electrostatic booster lens is between the upper and lower deflection units.

12. The multi-beam particle beam system of claim 1, further comprising a first setting mechanism, wherein the controller is configured to control the first setting mechanism so that the booster high voltage applied to the electrostatic booster lens is modifiable to modify at least one parameter selected from the group consisting of a working distance the first individual particle beams, and a numerical aperture of the first individual particle beams upon incidence on the object plane.

13. The multi-beam particle beam system of claim 12, further comprising a second setting mechanism different from the first setting mechanism, wherein the controller is configured to control the second setting mechanism to correct the modified parameter.

14. The multi-beam particle beam system of 13, wherein the second setting mechanism is configured to modify an excitation of the objective lens and/or of a field lens.

15. The multi-beam particle beam system of claim 13, wherein the second setting mechanism is configured to modify control of the collective scan deflector.

16. The multi-beam particle beam system of claim 13, comprising a beam tube arrangement, wherein:
the multi-beam particle beam system is configured so that the first individual particle beams are guided at least section-wise within the beam tube arrangement;
the beam tube arrangement comprises a beam tube interruption in the region of the crossover region;
the beam tube arrangement comprises a first beam tube section and a second beam tube section;
the first beam tube section defines an upper electrode of the electrostatic booster lens;
a central electrode of the electrostatic booster lens is within the beam tube interruption;
the second beam tube section defines a lower electrode of the electrostatic booster lens; and
the second setting mechanism is configured to apply a modified voltage to the second beam tube section.

17. (canceled)

18. (canceled)

19. The multi-beam particle beam system of claim 1, further comprising a telecentricity correction mechanism in the first particle-optical beam path, wherein:
the multi-beam particle beam system moreover has an intermediate image plane;
the telecentricity correction mechanism is between the multi-beam generator and the intermediate image plane;
the controller is configured to control the telecentricity correction mechanism so that an input telecentricity of the first individual particle beams is varied in the intermediate image plane.

20. The multi-beam particle beam system of claim 1, wherein the multi-beam particle beam system is configured so that the first individual particle beams has a telecentric incidence on the object plane.

21. The multi-beam particle beam system of claim 1, further comprising:
a detection system comprising a plurality of detection regions defining the third field;
a second particle-optical unit having a second particle-optical beam path, the second particle-optical unit being configured to image second individual particle beams, emanating from the incidence locations in the second field, onto the third field of the detection regions of the detection system; and
a beam splitter in the first particle-optical beam path between the multi-aperture arrangement and the objective lens, the beam splitter being in the second particle-optical beam path between the objective lens and the detection system,
wherein objective lens is configured to have the second individual particle beams pass therethrough.

22. A method, comprising:
providing a multi-beam particle beam system with a crossover region of first individual charged particle beams in an illumination beam path in an upper focal plane of an objective lens; and
section-wise significantly increasing a kinetic energy of the first individual particle beams in the crossover region for the purpose of significantly reducing the Coulomb interaction between the first individual charged particle beams.

23.-26. (canceled)
